(19) United States
(12) Patent Application Publication
(10) Pub. No.: US 2024/0087809 A1
(43) Pub. Date: Mar. 14, 2024

(54) ELECTRONIC COMPONENT

(71) Applicant: Murata Manufacturing Co., Ltd., Nagaokakyo-shi (JP)

(72) Inventor: Toshiyuki NAKAISO, Nagaokakyo-shi (JP)

(21) Appl. No.: 18/513,945

(22) Filed: Nov. 20, 2023

Related U.S. Application Data
(63) Continuation of application No. PCT/JP2022/019748, filed on May 10, 2022.

(30) Foreign Application Priority Data
May 31, 2021 (JP) 2021-090991

(51) Int. Cl. H01G 4/012; H01F 17/00; H01F 41/04; H01G 4/30; H01G 4/33; H01L 29/94

(52) U.S. Cl. CPC H01G 4/012; H01F 17/0013; H01F 41/042; H01G 4/306; H01G 4/33; H01L 29/94; H01G 4/252

(57) ABSTRACT

An electronic component that includes: a semiconductor substrate; an insulator layer on the semiconductor substrate; a lower electrode and an upper electrode that face the semiconductor substrate across the insulator layer; and a dielectric layer facing the semiconductor substrate across the insulator layer. The lower electrode, the upper electrode, and the dielectric layer configure a passive component. The insulator layer includes a conduction path passing through the insulator layer and electrically connecting the lower electrode and the semiconductor substrate.

### CROSS REFERENCE TO RELATED APPLICATIONS

The present application is a continuation of International application No. PCT/JP2022/019748, filed May 10, 2022, which claims priority to Japanese Patent Application No. 2021-090991, filed May 31, 2021, the entire contents of each of which are incorporated herein by reference.

### TECHNICAL FIELD

The present disclosure relates to an electronic component including a semiconductor substrate, such as a capacitor or an inductor.

### BACKGROUND ART

Japanese Patent No. 5458514 (hereinafter “Patent Literature 1”) discloses a semiconductor device in which a passive component such as a thin film capacitor is provided on a semiconductor substrate. A terminal electrode is provided on such a semiconductor substrate including a passive component, so that a surface mount electronic component is obtained.

In a general surface mount electronic component including a semiconductor substrate, the semiconductor substrate itself has no electrical function. The semiconductor substrate is used as a base material for keeping the entire shape.

### BRIEF SUMMARY OF THE DISCLOSURE

In the semiconductor device disclosed in Patent Literature 1, when a high-frequency current flows into the passive component (a function portion) due to the conductivity of the semiconductor substrate, a magnetic field generated by the high-frequency current is applied to the semiconductor substrate, As a result, an eddy current flows into the semiconductor substrate. As a result, the loss of a high-frequency signal is increased by the eddy current.

In view of the foregoing, exemplary embodiments of the present disclosure are directed to provide an electronic component capable of significantly reducing the loss of a high-frequency signal by significantly reducing an eddy current flowing into a semiconductor substrate.

An electronic component as one example of the present disclosure includes: a semiconductor substrate; an insulator layer on the semiconductor substrate; a conductor layer facing the semiconductor substrate across the insulator layer; and a non-conductor layer facing the semiconductor substrate across the insulator layer, wherein the conductor layer, or the conductor layer and a portion of the non-conductor layer, configure a passive component, and the insulator layer includes a conduction path that passes through the insulator layer and electrically connects the conductor layer and the semiconductor substrate.

An electronic component as another example of the present disclosure includes: a semiconductor substrate; a non-conductor layer on the semiconductor substrate; and a conductor layer facing the semiconductor substrate across the non-conductor layer, wherein the non-conductor layer, and the semiconductor substrate and the conductor layer form a capacitor.

According to the present disclosure, an electronic component in which the loss of a high-frequency signal is significantly reduced by significantly reducing an eddy current flowing into a semiconductor substrate is obtained.

### BRIEF DESCRIPTION OF THE DRAWINGS

FIG. 1A is a plan view of an electronic component 101 according to a first exemplary embodiment of the present disclosure, and FIG. 1B is a cross-sectional view taken along a line B-B in FIG. 1A.

FIG. 2 is a cross-sectional view in steps (1) to (6) of manufacturing the electronic component 101.

FIG. 3 is a cross-sectional view in steps (7) to (10) of manufacturing the electronic component 101.

FIG. 4 is a cross-sectional view in steps (11) and (12) of manufacturing the electronic component 101.

FIG. 5A is a plan view of an electronic component 102 according to a second exemplary embodiment of the present disclosure, and FIG. 5B is a cross-sectional view taken along a line B-B in FIG. 5A.

FIG. 6A is a plan view of an electronic component 103 according to a third exemplary embodiment of the present disclosure, and FIG. 6B is a cross-sectional view taken along a line B-B in FIG. 6A.

FIG. 7A, FIG. 7B, and FIG. 7C are views showing a structure of an electronic component 104 according to a fourth exemplary embodiment of the present disclosure.

FIG. 8 is a cross-sectional view in steps (1) to (6) of manufacturing the electronic component 104.

FIG. 9 is a cross-sectional view in steps (7) to (10) of manufacturing the electronic component 104.

FIG. 10 is a cross-sectional view in steps (11) and (12) of manufacturing the electronic component 104.

FIG. 11A and FIG. 11B are views showing a configuration of an electronic component as a comparative example of the first exemplary embodiment.

FIG. 12A and FIG. 12B are views showing a configuration of an electronic component as a comparative example of the fourth exemplary embodiment.

### DETAILED DESCRIPTION OF THE EXEMPLARY EMBODIMENTS

Hereinafter, a plurality of exemplary embodiments of the present disclosure will be described with reference to the attached drawings and several specific examples. In the drawings, components and elements assigned with the same reference numerals or symbols will represent identical components and elements. While an exemplary embodiment of the present disclosure is divided and described into a plurality of exemplary aspects for the sake of convenience in consideration of ease of description or understanding of main points, elements described in different exemplary embodiments are able to be partially replaced or combined with each other. In the second and subsequent exemplary embodiments, a description of features common to the first exemplary embodiment will be omitted, and only different features will be described. In particular, the same advantageous functions and effects by the same configurations will not be described one by one for each exemplary embodiment.

### First Exemplary Embodiment

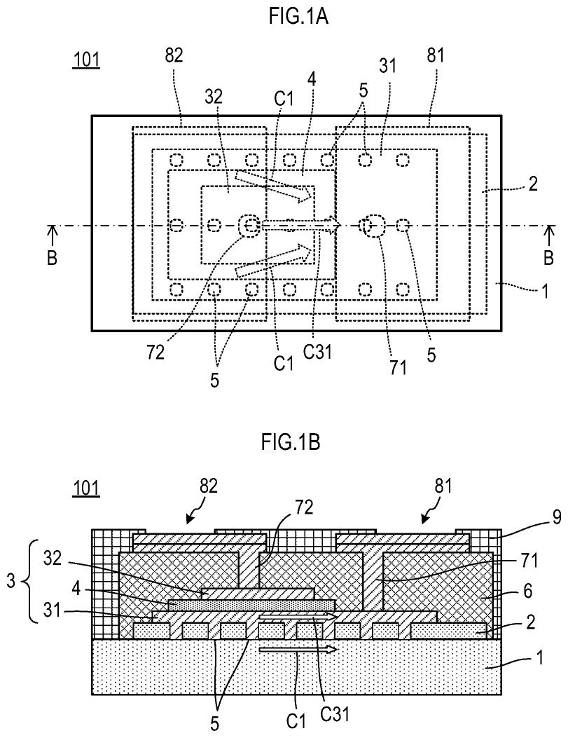

FIG. 1A is a plan view of an electronic component 101 according to a first exemplary embodiment of the present disclosure, and FIG. 1B is a cross-sectional view taken along a line B-B in FIG. 1A.

The electronic component 101 includes a semiconductor substrate 1, an insulator layer 2 provided on the semiconductor substrate 1, a conductor layer 3 provided so as to face the semiconductor substrate 1 across the insulator layer 2, and a dielectric layer 4 provided so as to face the semiconductor substrate 1 across the insulator layer 2. The dielectric layer 4 corresponds to a portion of a non-conductor layer according to the present disclosure. The conductor layer 3 includes a lower electrode 31 provided on the insulator layer 2, and an upper electrode 32 provided on the dielectric layer 4. In this example, the dielectric layer 4 is provided on the upper surface of the lower electrode 31.

In the present disclosure, the “conductor layer” is a name of a concept that includes, for example, an electrode and a conductor pattern. In addition, the “non-conductor layer” is a name of a concept that includes an insulator layer and a dielectric layer.

The insulator layer 2 includes a plurality of conduction paths 5 passing through the insulator layer 2 and electrically connecting the lower electrode 31 and the semiconductor substrate 1. It is to be noted that, although the present exemplary embodiment describes an example of the plurality of conduction paths 5 electrically connecting the lower electrode 31 and the semiconductor substrate 1, the conduction path 5 that provides a single current path that bypasses at least the semiconductor substrate 1 may be present.

A passivation layer 6 covering the insulator layer 2, the lower electrode 31, the dielectric layer 4, and the upper electrode 32 is provided on the surface of the semiconductor substrate 1.

A first terminal electrode 81 and a second terminal electrode 82 are provided on the surface of the passivation layer 6. A first extended electrode 71 electrically connecting the first terminal electrode 81 and the lower electrode 31 is provided between the first terminal electrode 81 and the lower electrode 31, and a second extended electrode 72 electrically connecting the second terminal electrode 82 and the upper electrode 32 is provided between the second terminal electrode 82 and the upper electrode 32.

The surface of the passivation layer 6, a portion of the surface of the first terminal electrode 81, and a portion of the surface of the second terminal electrode 82 are covered with a solder resist film 9.

The dielectric layer 4, and the lower electrode 31 and the upper electrode 32 that are provided across the dielectric layer 4 configure a passive component as a capacitor. In short, the electronic component 101 is a capacitor that uses the first terminal electrode 81 and the second terminal electrode 82 as a surface-mount connection terminal.

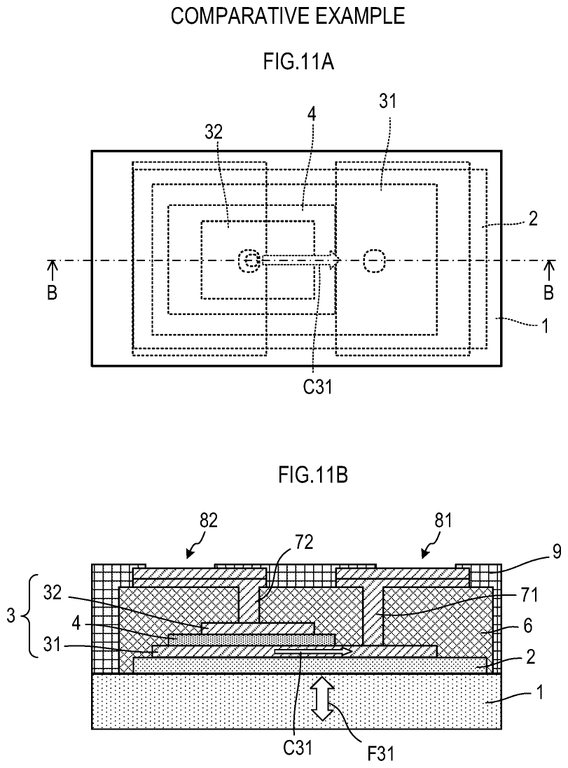

Herein, a configuration of an electronic component as a comparative example of the present exemplary embodiment is shown in FIG. 11A and FIG. 11B. FIG. 11A is a plan view of the electronic component as a comparative example, and FIG. 11B is a cross-sectional view taken along a line B-B in FIG. 11A. The electronic component as the comparative example does not include the conduction path 5 electrically connecting the lower electrode 31 and the semiconductor substrate 1.

In FIG. 11A and FIG. 11B, when a high-frequency voltage is applied between the first terminal electrode 81 and the second terminal electrode 82, a high-frequency current flows into the lower electrode 31. An arrow C31 in FIG. 11A and FIG. 11B conceptually shows the high-frequency current. Accordingly, a high-frequency magnetic field shown by an arrow F31 is generated in the semiconductor substrate 1. The high-frequency magnetic field guides an eddy current to the semiconductor substrate 1.

In contrast, since the electronic component 101 according to the present exemplary embodiment includes the plurality of conduction paths 5 electrically connecting the lower electrode 31 and the semiconductor substrate 1 in the insulator layer 2, the semiconductor substrate 1 is parallelly connected to the lower electrode 31. Therefore, a current flows into the semiconductor substrate 1 in approximately the same direction as the direction into which the current flowing into the lower electrode 31 flows. The arrow C31 in FIG. 1A and FIG. 1B conceptually shows the current flowing into the lower electrode 31, and the arrow Cl conceptually shows the current flowing into the semiconductor substrate 1. In this manner, since the semiconductor substrate 1 is not an isolated conductor and electrically connected to the lower electrode 31 as a path of the current that generates the magnetic flux shown by the arrow F31 in FIG. 11B at a plurality of points, the eddy current generated in the semiconductor substrate 1 is significantly reduced. The current (the arrow Cl) flowing into the semiconductor substrate 1 is a portion of the path of the current flowing into the capacitor, so that, unlike the eddy current, the current is not loss.

The semiconductor substrate 1 is a silicon substrate, for example, and may be a silicon intrinsic semiconductor substrate or a silicon impurity semiconductor substrate. The insulator layer 2 is an SiO₂ film being a thermal oxide film of a silicon substrate. The lower electrode 31 and the upper electrode 32 are an Al film or a Cu film. The dielectric layer 4 is an SiO₂ film. The passivation layer 6 is an SiN film and a film of an organic material provided on the SiN film. Alternatively, the passivation layer 6 is an SiN film. The first extended electrode 71 and the second extended electrode 72 are Cu films (Cu/Ti films) including a Ti film as a base. The first terminal electrode 81 and the second terminal electrode 82 are Au films (Au/Ni films) including an Ni film as a base. The solder resist film 9 is a film of an organic material.

Examples of materials and thickness sizes of each portion described above are shown below.

TABLE 1

| COMPONENT | MATERIAL | SIZE |
|---|---|---|
| TERMINAL ELECTRODE | Au/Ni | 0.1/3.0 μm |
| EXTENDED ELECTRODE | Cu/Ti | 1.0/0.1 μm |
| SOLDER RESIST FILM | ORGANIC FILM | 5.0 μm |
| PASSIVATION LAYER | ORGANIC FILM/ | 5.0/0.8 μm 0.8 μm |
| | SiN or SiN | |
| ELECTRODE | Al or Cu | 1.0 μm |
| INSULATOR LAYER | SiO2 | 1.0 μm |
| DIELECTRIC LAYER | SiO2 | 1.0 μm |
| SEMICONDUCTOR | Si | |
| SUBSTRATE | | |

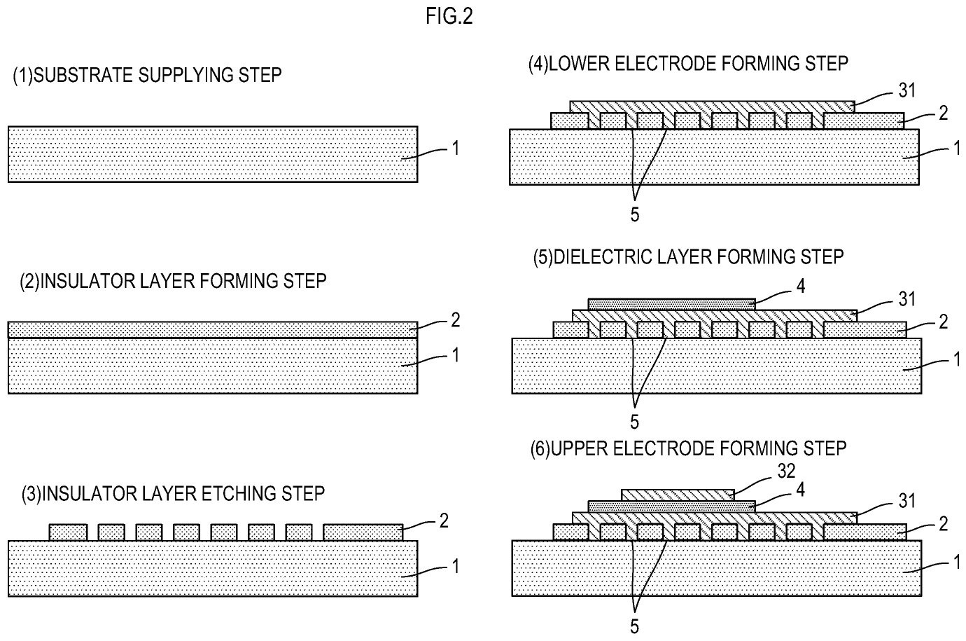

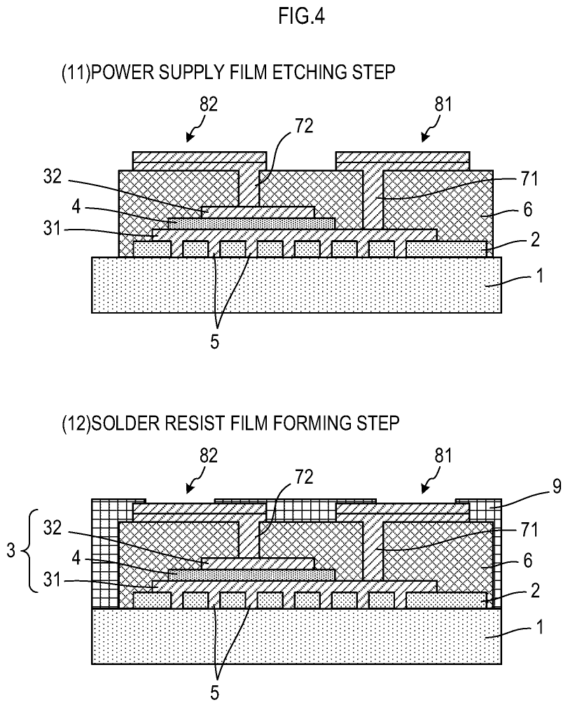

Subsequently, an example of a method of manufacturing the electronic component 101 will be described based on FIG. 2 from FIG. 4.

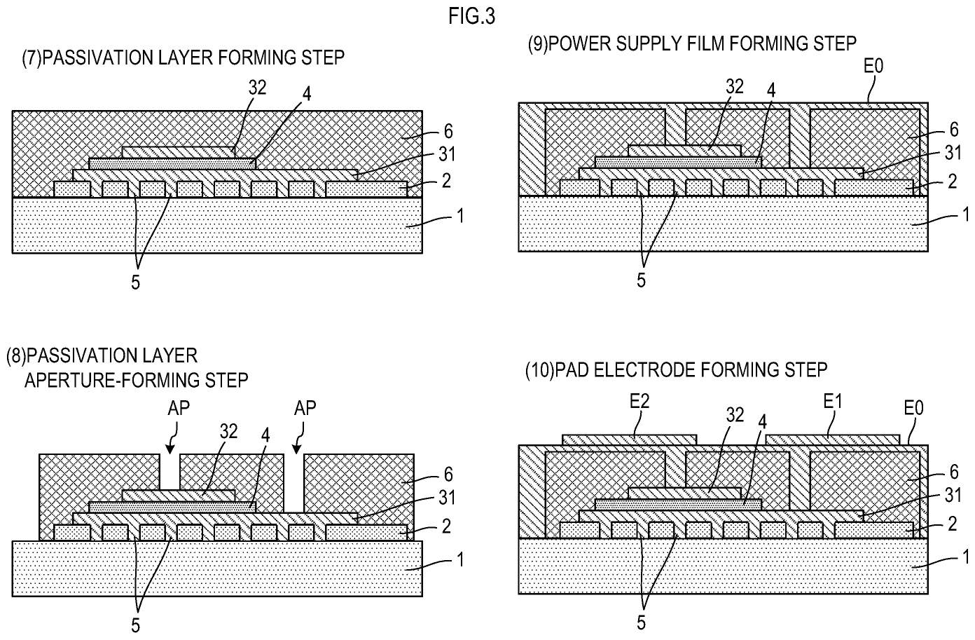

FIG. 2 is a cross-sectional view in steps (1) to (6), FIG. 3 is a cross-sectional view in steps (7) to (10), and FIG. 4 is a cross-sectional view in steps (11) and (12). However, any figure represents a single electronic component unit.

The step (1) is a substrate supplying step and supplies a silicon substrate as a semiconductor substrate 1 to manufacturing equipment.

The step (2) is an insulator layer forming step and forms an SiO₂ film as an insulator layer 2 by thermally oxidizing the surface of the semiconductor substrate 1.

The step (3) is an insulator layer etching step and forms a hole for forming a conduction path to be shown later by etching a predetermined portion of the insulator layer 2.

The step (4) is a lower electrode forming step and forms a conduction path 5 and a lower electrode 31 by sputtering Al or Cu on the insulator layer 2.

The step (5) is a dielectric layer forming step and forms an SiO₂ film as a dielectric layer 4 on the upper surface of the lower electrode 31.

The step (6) is an upper electrode forming step and forms an upper electrode 32 by sputtering Al or Cu on the upper surface of the dielectric layer 4.

The step (7) is a passivation layer forming step and forms a passivation layer 6 by covering the surface of the semiconductor substrate 1, the insulator layer 2, the lower electrode 31, the dielectric layer 4, and the upper electrode 32 with a passivation film.

The step (8) is a passivation layer aperture-forming step and forms an aperture AP in a position in which a first extended electrode and a second extended electrode to be shown later.

The step (9) is a power supply film forming step and forms a power supply film E0 by sputtering a Ti film on the surface of the passivation layer 6 and then sputtering a Cu film on the Ti film.

The step (10) is a pad electrode forming step, and forms pad electrodes E1 and E2 by sputtering a Ni film on the power supply film E0 and then sputtering an Au film on the Ni film.

The step (11) is a power supply film etching step, and forms a first extended electrode 71, a second extended electrode 72, a first terminal electrode 81, and a second terminal electrode 82 by etching and removing an exposed portion of the power supply film E0 shown in the step (10).

The step (12) is a solder resist film forming step and covers with a solder resist film 9 the surface of the passivation layer 6, a portion of the surface of the first terminal electrode 81, and a portion of the surface of the second terminal electrode 82.

Although the above example exemplifies the electronic component including the first terminal electrode 81 and the second terminal electrode 82, the present disclosure is similarly applicable to an electronic component including a capacitor configured by the lower electrode 31, the dielectric layer 4, and the upper electrode 32.

### Second Exemplary Embodiment

The second exemplary embodiment exemplifies an electronic component in which a portion of a path of a current flowing into a passive component is configured by a portion of the semiconductor substrate.

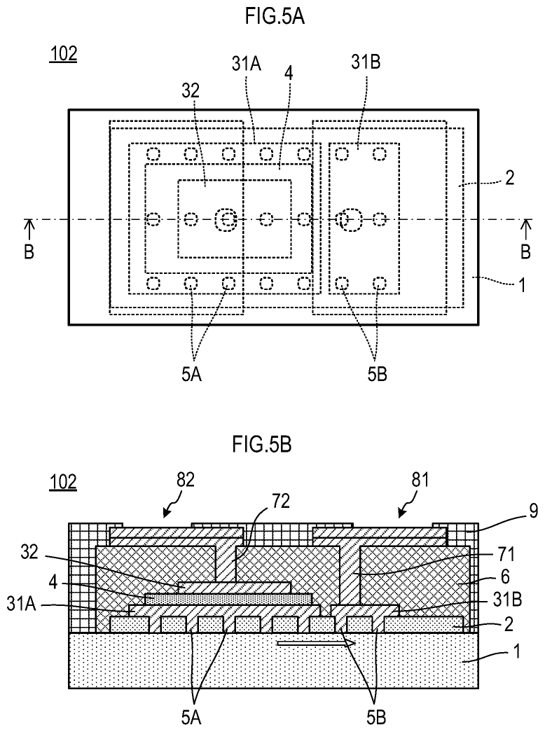

FIG. 5A is a plan view of an electronic component 102 according to the second exemplary embodiment of the present disclosure, and FIG. 5B is a cross-sectional view taken along a line B-B in FIG. 5A.

The electronic component 102 includes a semiconductor substrate 1, an insulator layer 2 provided on the semiconductor substrate 1, a first lower electrode 31A and a second lower electrode 31B that are provided so as to face the semiconductor substrate 1 across the insulator layer 2, and a dielectric layer 4 provided so as to face the semiconductor substrate 1 across the insulator layer 2. The dielectric layer 4 corresponds to a portion of a non-conductor layer according to the present disclosure. The first lower electrode 31A and the second lower electrode 31B that are provided on the insulator layer 2, and the upper electrode 32 provided on the dielectric layer 4 are portions of the conductor layer according to the present disclosure.

The electronic component 102 according to the present exemplary embodiment includes the lower electrode divided into the first lower electrode 31A and the second lower electrode 31B, and the dielectric layer 4 provided on the upper surface of the first lower electrode 31A.

The insulator layer 2 includes a first conduction path 5A passing through the insulator layer 2 and electrically connecting the first lower electrode 31A and the semiconductor substrate 1. In addition, the insulator layer 2 includes a second conduction path 5B passing through the insulator layer 2 and electrically connecting the second lower electrode 31B and the semiconductor substrate 1.

A passivation layer 6 covering the insulator layer 2, the first lower electrode 31A, the second lower electrode 31B, the dielectric layer 4, and the upper electrode 32 is provided on the surface of the semiconductor substrate 1.

A first terminal electrode 81 and a second terminal electrode 82 are provided on the surface of the passivation layer 6. A first extended electrode 71 electrically connecting the first terminal electrode 81 and the second lower electrode 31B is provided between the first terminal electrode 81 and the second lower electrode 31B, and a second extended electrode 72 electrically connecting the second terminal electrode 82 and the upper electrode 32A is provided between the second terminal electrode 82 and the upper electrode 32A.

The surface of the passivation layer 6, a portion of the surface of the first terminal electrode 81, and a portion of the surface of the second terminal electrode 82 are covered with a solder resist film 9.

The dielectric layer 4, and the first lower electrode 31A and the upper electrode 32 that are provided across the dielectric layer 4 configure a passive component as a capacitor. A current path of the first lower electrode 31A, the first conduction path 5A, the semiconductor substrate 1, the second conduction path 5B, and the second lower electrode 31B is configured between the first lower electrode 31A and the second lower electrode 31B. In short, the electronic component 102 is a capacitor that uses the first terminal electrode 81 and the second terminal electrode 82 as a surface-mount connection terminal.

The semiconductor substrate 1 is a silicon impurity semiconductor substrate. In the electronic component 102 according to the present exemplary embodiment, the semiconductor substrate 1 configures a portion of a path of a current flowing into the passive component. Therefore, a current flows into the semiconductor substrate 1 in approximately the same direction as the direction into which the current flowing into the lower electrode 31A flows. The current flowing into the semiconductor substrate 1 is a portion of the path of the current flowing into the capacitor, so that, unlike the eddy current, the current is not loss.

Although the above example exemplifies the electronic component including the first terminal electrode 81 and the second terminal electrode 82, the present disclosure is similarly applicable to an electronic component including a capacitor configured by the first lower electrode 31A, the dielectric layer 4, and the upper electrode 32.

### Third Exemplary Embodiment

The third exemplary embodiment exemplifies an electronic component in which a portion of a path of a current flowing into a passive component is configured by a portion of the semiconductor substrate.

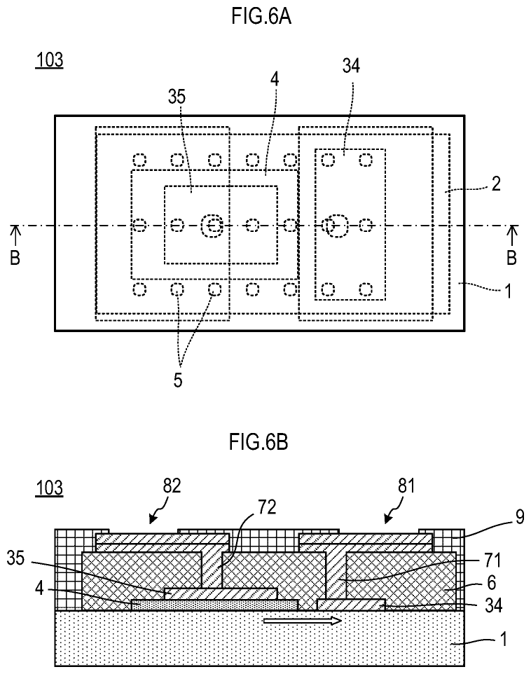

FIG. 6A is a plan view of an electronic component 103 according to the third exemplary embodiment of the present disclosure, and FIG. 6B is a cross-sectional view taken along a line B-B in FIG. 6A.

The electronic component 103 includes a semiconductor substrate 1, and a dielectric layer 4 and a substrate electrode 34 that are provided on the semiconductor substrate 1. The dielectric layer 4 corresponds to a portion of a non-conductor layer according to the present disclosure. A dielectric layer electrode 35 is provided on the upper surface of the dielectric layer 4. The dielectric layer electrode 35 is an example of a conductor layer according to the present disclosure.

In the electronic component 103 according to the present exemplary embodiment, an electrode is not provided under the dielectric layer 4, and the semiconductor substrate 1 functions as a lower electrode of the dielectric layer 4.

A passivation layer 6 covering the substrate electrode 34, the dielectric layer 4, and the dielectric layer electrode 35 is provided on the surface of the semiconductor substrate 1.

A first terminal electrode 81 and a second terminal electrode 82 are provided on the surface of the passivation layer 6. A first extended electrode 71 electrically connecting the first terminal electrode 81 and the substrate electrode 34 is provided between the first terminal electrode 81 and the substrate electrode 34, and a second extended electrode 72 electrically connecting the second terminal electrode 82 and the dielectric layer electrode 35 is provided between the second terminal electrode 82 and the dielectric layer electrode 35.

The surface of the passivation layer 6, a portion of the surface of the first terminal electrode 81, and a portion of the surface of the second terminal electrode 82 are covered with a solder resist film 9.

The dielectric layer 4, and the semiconductor substrate 1 and the dielectric layer electrode 35 that are provided across the dielectric layer 4 configure a passive component as a capacitor. In short, the electronic component 103 is a capacitor that uses the first terminal electrode 81 and the second terminal electrode 82 as a surface-mount connection terminal.

The semiconductor substrate 1 is a silicon impurity semiconductor substrate. In the electronic component 103 according to the present exemplary embodiment, the semiconductor substrate 1 configures a portion of a path of a current flowing into the passive component (the capacitor). Unlike an eddy current, the current is not loss.

Although the above example exemplifies the electronic component including the first terminal electrode 81 and the second terminal electrode 82, the present disclosure is similarly applicable to an electronic component including a capacitor configured by the semiconductor substrate 1, the dielectric layer 4, dielectric layer electrode 35, and the substrate electrode 34.

### Fourth Exemplary Embodiment

The fourth exemplary embodiment exemplifies an electronic component including an inductor.

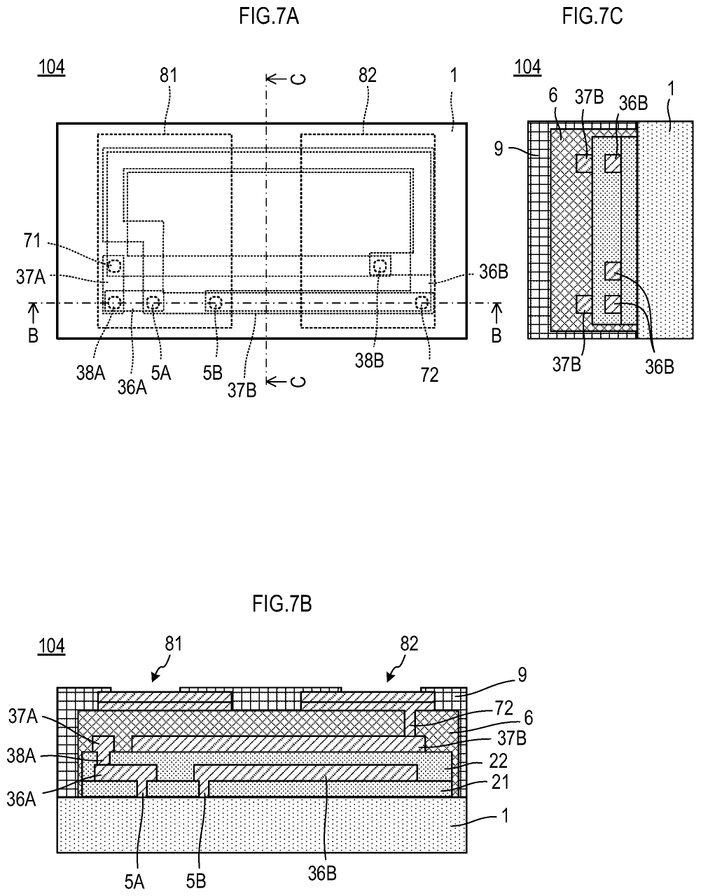

FIG. 7A, FIG. 7B, and FIG. 7C are views showing a structure of an electronic component 104 according to the fourth exemplary embodiment of the present disclosure. FIG. 7A is a plan view of the electronic component 104, FIG. 7B is a cross-sectional view taken along a line B-B in FIG. 7A, and FIG. 7C is a cross-sectional view taken along a line C-C in FIG. 7A.

The electronic component 104 includes a semiconductor substrate 1, insulator layers 21 and 22 that are provided on the semiconductor substrate 1, conductor patterns 36A and 36B that are provided on the insulator layer 21, conductor patterns 37A and 37B that are provided on the insulator layer 22, and conductor patterns 38A and 38B that are provided on the insulator layer 22. The conductor patterns 36A, 36B, 37A, 37B, 38A, and 38B correspond to a conductor pattern according to the present disclosure.

The insulator layer 21 includes conduction paths 5A and 5B passing through the insulator layer 21 and electrically connecting the conductor patterns 36A and 36B and the semiconductor substrate 1.

A passivation layer 6 covering the insulator layers 21 and 22 and the conductor patterns 37A and 37B is provided on the surface of the semiconductor substrate 1.

A first terminal electrode 81 and a second terminal electrode 82 are provided on the surface of the passivation layer 6. A first extended electrode 71 electrically connecting the first terminal electrode 81 and the conductor pattern 37A is provided between the first terminal electrode 81 and the conductor pattern 37A, and a second extended electrode 72 electrically connecting the second terminal electrode 82 and the conductor pattern 37B is provided between the second terminal electrode 82 and the conductor pattern 37B.

The surface of the passivation layer 6, a portion of the surface of the first terminal electrode 81, and a portion of the surface of the second terminal electrode 82 are covered with a solder resist film 9.

The semiconductor substrate 1 is a silicon impurity semiconductor substrate. The conductor patterns 36A, 36B, 37A, and 37B and a portion of the semiconductor substrate 1 configure a passive component as an inductor. In short, the electronic component 104 is an inductor that uses the first terminal electrode 81 and the second terminal electrode 82 as a surface-mount connection terminal.

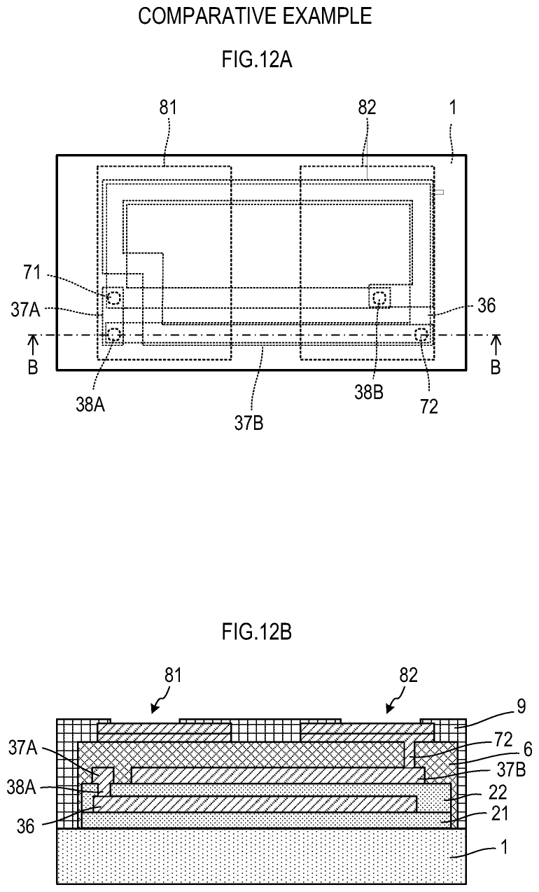

Herein, a configuration of an electronic component as a comparative example of the present exemplary embodiment is shown in FIG. 12A and FIG. 12B. FIG. 12A is a plan view of the electronic component as a comparative example, and FIG. 12B is a cross-sectional view taken along a line B-B in FIG. 12A. The electronic component as the comparative example does not include a conduction path electrically connecting the conductor pattern 36 and the semiconductor substrate 1.

In FIG. 12A and FIG. 12B, when a high-frequency current is applied between the first terminal electrode 81 and the second terminal electrode 82, the high-frequency current flows into the conductor patterns 36, 37A, and 37B. Accordingly, a high-frequency magnetic field is generated in the semiconductor substrate 1, and the high-frequency magnetic field guides an eddy current to the semiconductor substrate 1.

In contrast, in the electronic component 104 of the present exemplary embodiment, the semiconductor substrate 1 is not an isolated conductor and configures a portion of a path of a current flowing into the passive component (the inductor). Unlike an eddy current, the current is not loss.

Examples of materials and thickness sizes of each portion of the electronic component 104 described above are shown below.

TABLE 2

| COMPONENT | MATERIAL | SIZE |
|---|---|---|
| TERMINAL ELECTRODE | Au/Ni | 0.1/3.0 μm |
| EXTENDED ELECTRODE | Cu/Ti | 1.0/0.1 μm |
| SOLDER RESIST FILM | ORGANIC FILM | 5.0 μm |
| PASSIVATION LAYER | ORGANIC FILM/ | 5.0/0.8 μm 0.8 μm |
| | SiN or SiN | |
| CONDUCTOR PATTERN | Al or Cu | 1.0 μm |
| INSULATOR LAYER | SiO2 | 1.0 μm |
| SEMICONDUCTOR | Si | |
| SUBSTRATE | | |

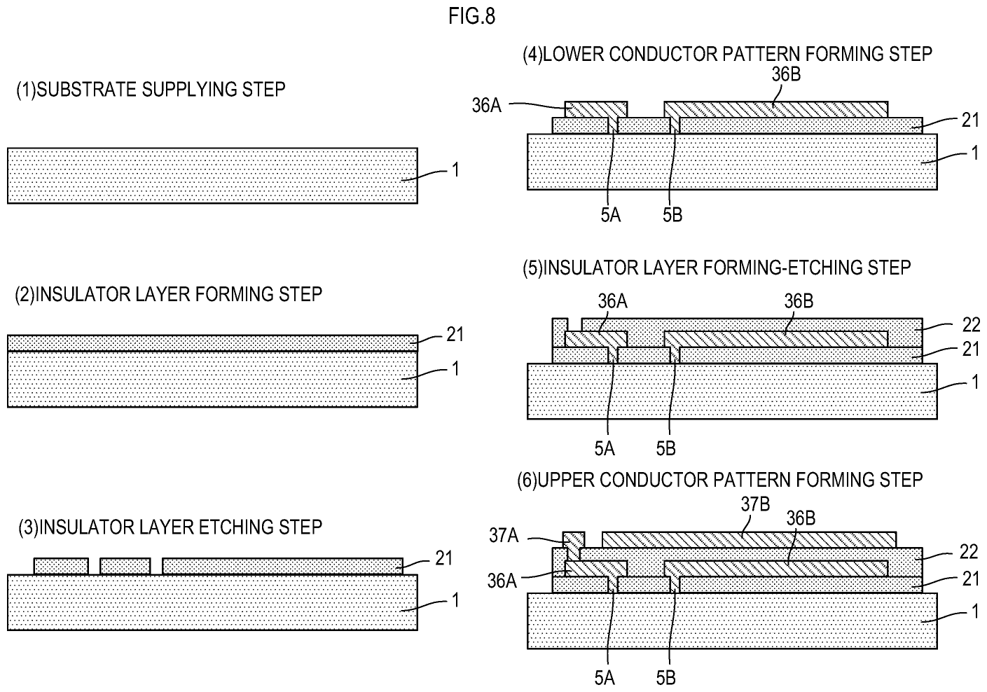

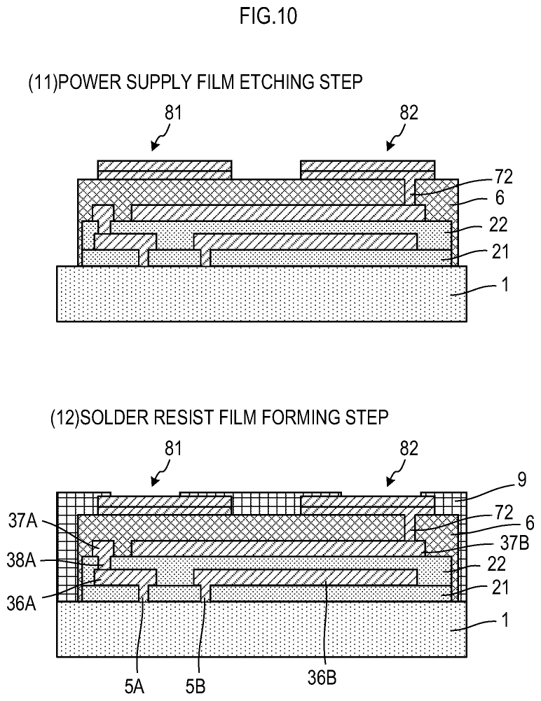

Subsequently, an example of a method of manufacturing the electronic component 104 will be described based on FIG. 8 from FIG. 10.

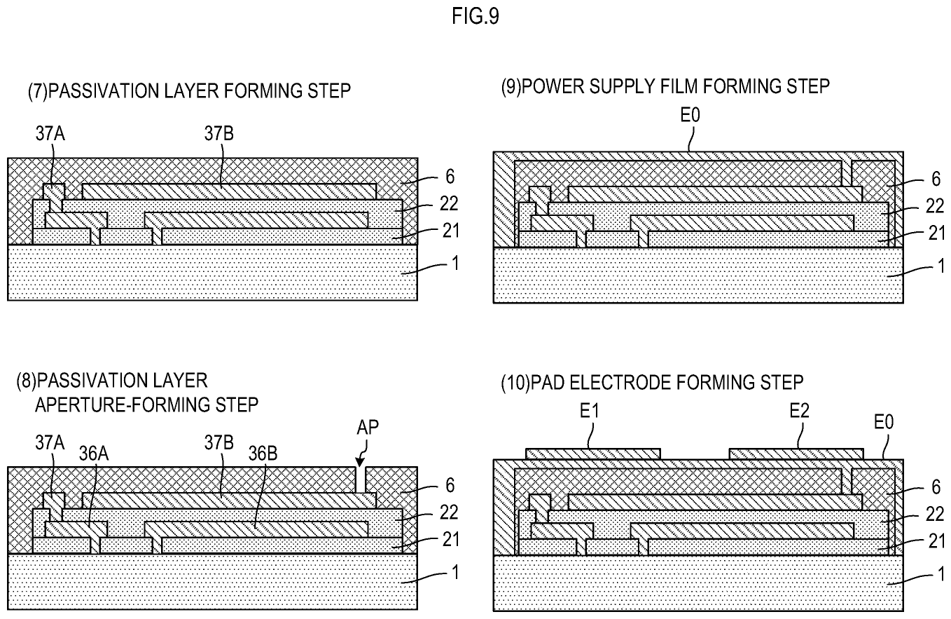

FIG. 8 is a cross-sectional view in steps (1) to (6), FIG. 9 is a cross-sectional view in steps (7) to (10), and FIG. 10 is a cross-sectional view in steps (11) and (12). However, any figure represents a single electronic component unit.

The step (1) is a substrate supplying step and supplies a silicon substrate as a semiconductor substrate 1 to manufacturing equipment.

The step (2) is an insulator layer forming step and forms an SiO₂ film as an insulator layer 2 by thermally oxidizing the surface of the semiconductor substrate 1.

The step (3) is an insulator layer etching step and forms a hole for forming a conduction path to be shown later by etching a predetermined portion of the insulator layer 2.

The step (4) is a lower conductor pattern forming step, and forms conduction paths 5A and 5B, and conductor patterns 36A and 36B by sputtering Al or Cu on the insulator layer 2.

The step (5) is an insulator layer forming-etching step and forms an SiO₂ film as an insulator layer 22 on the upper surface of the conductor patterns 36A and 36B and on the upper surface of the insulator layer 21.

The step (6) is an upper conductor pattern forming step, and forms conductor patterns 37A, 37B, 38A, and 38B by sputtering Al or Cu on the insulator layer 22.

The step (7) is a passivation layer forming step and forms a passivation layer 6 by covering the surface of the semiconductor substrate 1, the insulator layers 21 and 22, and the conductor patterns 37A and 37B with a passivation film.

The step (8) is a passivation layer aperture-forming step and forms an aperture AP in a position in which a first extended electrode and a second extended electrode to be shown later.

The step (9) is a power supply film forming step and forms a power supply film E0 by sputtering a Ti film on the surface of the passivation layer 6 and then sputtering a Cu film on the Ti film.

The step (10) is a pad electrode forming step, and forms pad electrodes E1 and E2 by sputtering a Ni film on the power supply film E0 and then sputtering an Au film on the Ni film.

The step (11) is a power supply film etching step, and forms a first extended electrode (the first extended electrode 71 shown in FIG. 7A), a second extended electrode 72, a first terminal electrode 81, and a second terminal electrode 82 by etching and removing an exposed portion of the power supply film E0 shown in the step (10).

The step (12) is a solder resist film forming step and covers with a solder resist film 9 the surface of the passivation layer 6, a portion of the surface of the first terminal electrode 81, and a portion of the surface of the second terminal electrode 82.

Although the above example exemplifies the electronic component including the first terminal electrode 81 and the second terminal electrode 82, the present disclosure is similarly applicable to an electronic component including an inductor configured by the conductor patterns 36A, 36B, 37A, 37B, 38A, and 38B and the insulator layers 21 and 22.

It is to be noted that, although the first, second, and third exemplary embodiments show the electronic component including a capacitor as a passive component, and the fourth exemplary embodiment shows the electronic component including an inductor as a passive component, an electronic component including a passive component including both a capacitor and an inductor is able to be configured similarly. In addition, an electronic component including a passive component including a plurality of capacitors and a plurality of inductors is also able to be configured.

Finally, the present disclosure is not limited to the foregoing exemplary embodiments. Various modifications or changes can be appropriately made by those skilled in the art. The scope of the present disclosure is defined not by the foregoing exemplary embodiments but by the following claims. Furthermore, the scope of the present disclosure is intended to include all possible modifications or changes from the exemplary embodiments within the scopes of the claims and the scopes of equivalents.

### REFERENCE SIGNS LIST

AP—aperture
E0—power supply film
E1, E2—pad electrode
1—semiconductor substrate
2—insulator layer
3—conductor layer
4—dielectric layer (non-conductor layer)
5—conduction path
5A—first conduction path
5B—second conduction path
6—passivation layer (non-conductor layer)
9—solder resist film (non-conductor layer)
21, 22—insulator layer
31—lower electrode
31A—first lower electrode
31B—second lower electrode
32—upper electrode
34—substrate electrode
35—dielectric layer electrode
36, 36A, 36B, 37A, 37B, 38A, 38B—conductor pattern
71—first extended electrode
72—second extended electrode
81—first terminal electrode
82—second terminal electrode
101, 102, 103, 104—electronic component

1. An electronic component comprising:
a semiconductor substrate;
an insulator layer on the semiconductor substrate;
a conductor layer facing the semiconductor substrate across the insulator layer; and
a non-conductor layer facing the semiconductor substrate across the insulator layer, wherein:
the conductor layer, or the conductor layer and a portion of the non-conductor layer, configure a passive component; and
the insulator layer includes a conduction path passing through the insulator layer and electrically connecting the conductor layer and the semiconductor substrate.

2. The electronic component according to claim 1, wherein:
the conductor layer is configured as a conductor pattern;
the electronic component further comprises:
a first terminal electrode on a surface of the non-conductor layer;
a second terminal electrode on the surface of the non-conductor layer;
a first extended electrode electrically connecting the first terminal electrode and the conductor pattern;
a second extended electrode electrically connecting the second terminal electrode and the conductor pattern; and
the conduction path electrically connects the conductor pattern and the semiconductor substrate; and
the first terminal electrode and the second terminal electrode are electrically connected with each other through the semiconductor substrate.

3. The electronic component according to claim 2, wherein the semiconductor substrate is an impurity semiconductor substrate.

4. The electronic component according to claim 1, wherein:
the conductor layer is configured as a linear conductor pattern;
the electronic component further comprises:
a first terminal electrode on a surface of the non-conductor layer;
a second terminal electrode on the surface of the non-conductor layer;
a first extended electrode electrically connecting the first terminal electrode and the conductor pattern;
a second extended electrode electrically connecting the second terminal electrode and the conductor pattern; and
the conduction path electrically connects the linear conductor pattern and the semiconductor substrate;
and
the conductor pattern and a portion of the semiconductor substrate form an inductor.

5. The electronic component according to claim 1, wherein:
the conductor layer includes:
a lower electrode on the insulator layer; and
an upper electrode on the non-conductor layer;
the electronic component further comprises:
a first terminal electrode on a surface of the non-conductor layer;
a second terminal electrode on the surface of the non-conductor layer;
a first extended electrode electrically connecting the first terminal electrode and the lower electrode; and
a second extended electrode electrically connecting the second terminal electrode and the upper electrode; and
the non-conductor layer, and the lower electrode and the upper electrode form a capacitor.

6. The electronic component according to claim 5, wherein the insulator layer includes a plurality of the conduction paths passing through the insulator layer and electrically connecting the lower electrode layer and the semiconductor substrate.

7. The electronic component according to claim 5, wherein:
the lower electrode includes:
a first lower electrode; and
a second lower electrode separated from the first lower electrode; and
the conduction path includes:
a first conduction path electrically connecting the first lower electrode and the semiconductor substrate; and
a second conduction path electrically connecting the second lower electrode and the semiconductor substrate.

8. The electronic component according to claim 7, wherein the semiconductor substrate is an impurity semiconductor substrate.

9. The electronic component according to claim 1, wherein the insulator layer includes a plurality of the conduction paths passing through the insulator layer and electrically connecting the conductor layer and the semiconductor substrate.

10. The electronic component according to claim 1, wherein:
the semiconductor substrate is a silicon substrate; and
the non-conductor layer is a thermal oxide film of the silicon substrate.

11. An electronic component comprising:
a semiconductor substrate;
a non-conductor layer on the semiconductor substrate; and
a conductor layer facing the semiconductor substrate across the non-conductor layer, wherein the non-conductor layer, and the semiconductor substrate and the conductor layer form a capacitor.

12. The electronic component according to claim 11, wherein the semiconductor substrate is an impurity semiconductor substrate.
